(19) United States
(12) Patent Application Publication
(10) Pub. No.: US 2008/0112124 A1
(43) Pub. Date: May 15, 2008

(54) Flush form factor for USB storage device

(76) Inventor: Rod R. Rozman, Placerville, CA (US)

Correspondence Address: INTEL CORPORATION;c/o INTELLEVATE, LLC, P.O. BOX 52050, MINNEAPOLIS, MN, 55402, US

(21) Appl. No.: 11/600,409

(22) Filed: Nov. 15, 2006

(51) Int. Cl. H05K 5/00; B23P 11/00

(52) U.S. Cl. 361/684; 29/428

(57) ABSTRACT

A solid-state non-volatile storage device may be configured such that, when plugged into a computer system, the storage device is approximately flush with the side of the computer system, with the storage device's smallest overall dimension approximately perpendicular to the side of the computer system.

### BACKGROUND

Advances in memory technology have made it possible to place a great deal of non-volatile memory storage into a physically small package. For example, so-called ‘flash drives’ may contain a gigabyte or more of flash memory in a package smaller than a pack of chewing gum. Connecting such devices to a computer through a universal serial bus (USB) interface is also popular. Since the package is small compared to a USB cable, such devices typically plug directly into a USB port without using a cable. For ease of handling, these USB storage devices are usually approximately rectangular, with the USB plug on the smallest side and the long dimension of the rectangle protruding out perpendicular to the side of the computer chassis. While this orientation makes plugging and unplugging the device easy, it also makes the device vulnerable to damage, since the protruding device can be hit by nearby objects. This is especially true when USB storage devices are used with laptop and notebook computers, which are frequently moved about and used in small spaces.

### BRIEF DESCRIPTION OF THE DRAWINGS

Some embodiments of the invention may be understood by referring to the following description and accompanying drawings that are used to illustrate embodiments of the invention. In the drawings:

FIGS. 1A and 1B show plug-in non-volatile mass storage devices, according to some embodiments of the invention.

FIG. 2 shows an integrated circuit contained within a flash drive body, according to an embodiment of the invention.

FIG. 3 shows a computer system with a storage device plugged into it, according to an embodiment of the invention.

FIG. 4 shows an extension for a plug on a storage device, according to an embodiment of the invention.

### DETAILED DESCRIPTION

In the following description, numerous specific details are set forth. However, it is understood that embodiments of the invention may be practiced without these specific details. In other instances, well-known circuits, structures and techniques have not been shown in detail in order not to obscure an understanding of this description.

References to “one embodiment”, “an embodiment”, “example embodiment”, “various embodiments”, etc., indicate that the embodiment(s) of the invention so described may include particular features, structures, or characteristics, but not every embodiment necessarily includes the particular features, structures, or characteristics. Further, some embodiments may have some, all, or none of the features described for other embodiments.

In the following description and claims, the terms “coupled” and “connected,” along with their derivatives, may be used. It should be understood that these terms are not intended as synonyms for each other. Rather, in particular embodiments, “connected” is used to indicate that two or more elements are in direct physical or electrical contact with each other. “Coupled” is used to indicate that two or more elements co-operate or interact with each other, but they may or may not be in direct physical or electrical contact.

As used in the claims, unless otherwise specified the use of the ordinal adjectives “first”, “second”, “third”, etc., to describe a common element, merely indicate that different instances of like elements are being referred to, and are not intended to imply that the elements so described must be in a given sequence, either temporally, spatially, in ranking, or in any other manner.

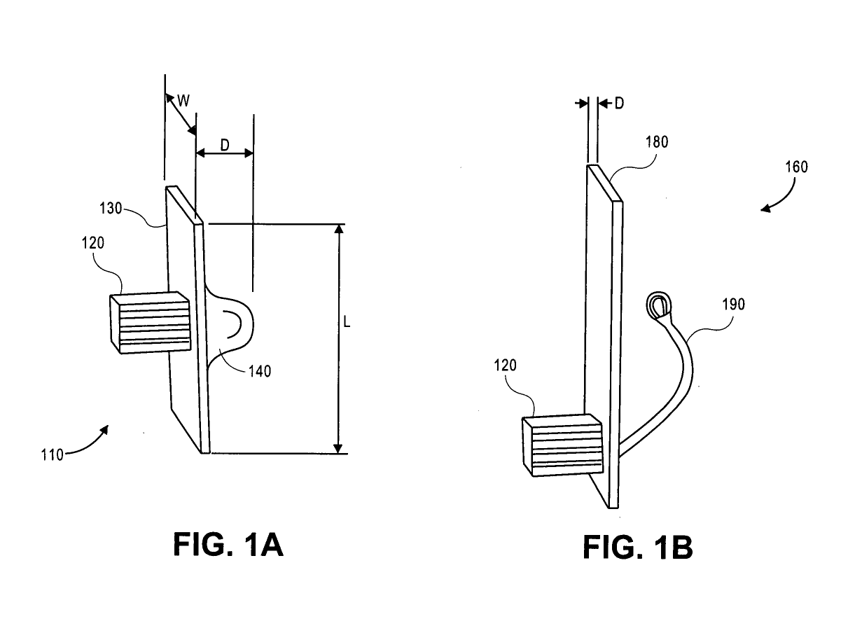

FIGS. 1A and 1B show plug-in non-volatile mass storage devices, according to some embodiments of the invention. The illustrated embodiment of FIG. 1A shows a storage device 110 comprising a body 130, which may house the integrated circuit(s) containing the memory arrays. Plug 120 may be plugged into a socket in another device (not shown in FIG. 1A) to provide an electrical signal interface between that other device and the memory arrays housed in body 130. In some embodiments the type of connection may be a universal serial bus (USB) connection, but other embodiments may use other techniques. Because of the flush form factor of body 130, when the storage device 110 is plugged into a computer system it may be difficult to grip it for unplugging. To facilitate this grip, a handle 140 may be attached to the body 130, so that a user may easily grip the handle and pull on it to unplug the storage device.

In some embodiments, the storage device 110 may be a storage device commonly referred to as a ‘flash drive’ (e.g., flash memory organized as a mass storage system). The relative overall dimensions and configuration of the body 130 may be significantly different than on conventional flash drives. In the illustrated storage device 110, both length (L) and width (W) are measured perpendicular to the insertion axis of the plug, which will make those two dimensions approximately parallel to the side of the device into which the storage device 110 is to be connected. The insertion axis is the direction in which the plug is moved when it is being inserted into a mating connector. Depth (D) is measured parallel to the insertion axis, and therefore perpendicular to L and W. This depth may include the handle 140. Various embodiments of the invention differ from conventional devices in that dimension D is smaller than L or W (in some embodiments much smaller), so that when the storage device is plugged into a computer system, the storage device only sticks out a short distance, while most of the bulk of the storage device is close to the surface of the computer system. In some embodiments, most of dimension D will be taken up by the handle, which may be smoothly contoured so that it will not catch or snag on other objects. In some embodiments, dimension D may be less than one-half inch, or even less than one-quarter inch.

FIG. 1B shows a storage device 160 that is similar to device 110, but with a different physical configuration. The primary differences are that the plug 170 is located near one end of body 180 (rather than in the center as shown in FIG. 1A), and the handle 190 is a flexible cord rather than a rigid protrusion. Although only one end of the cord is shown attached to the body, in some embodiments both ends of the cord may be attached to the body. Because a flexible cord may hang limply next to the body 180 when the storage device is plugged in, the effective dimension D may be little more than the thickness of body 180 (as shown in FIG. 1B). In some embodiments, dimension D may be less than one-quarter inch, or even less than one-eighth inch. FIGS. 1A and 1B show two particular physical configurations, but other embodiments may have different configurations.

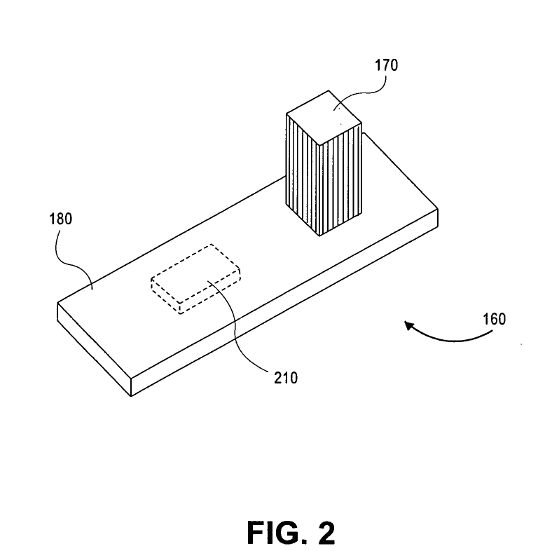

Another factor that may influence the minimum depth D is the orientation of the integrated circuit(s) that are contained within the body. FIG. 2 shows an integrated circuit contained within a flash drive body, according to an embodiment of the invention. In the illustrated embodiment, the integrated circuit 210 is oriented so that it's own thinnest dimension is perpendicular to the insertion axis of plug 170. This allows body 180 to be quite thin in the same direction. In some embodiments, integrated circuit 210 may contain a non-volatile memory array and/or a controller for the non-volatile memory array. Although only a single integrated circuit 210 is shown, some embodiments may contain multiple integrated circuits, each oriented with their thinnest dimension parallel to the insertion axis of plug 170, while still other embodiments may contain one or more integrated circuits mounted to a substrate that is oriented with its thinnest dimension parallel to the insertion axis of plug 170.

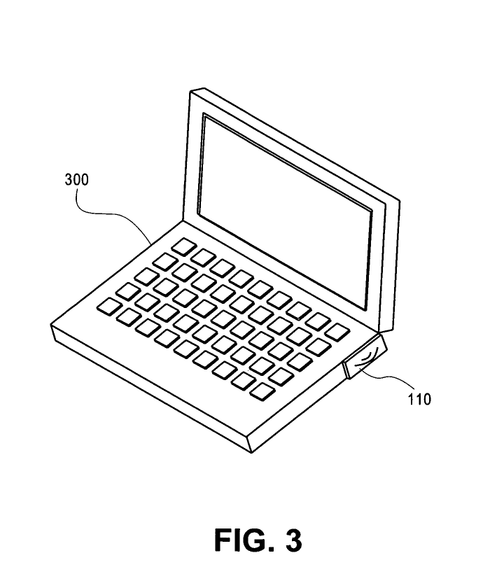

FIG. 3 shows a computer system with a storage device plugged into it, according to an embodiment of the invention. In the illustrated embodiment, computer system 300 is shown as a notebook computer or laptop computer, but other embodiments may use other types of computer systems (e.g., a desktop computer system, a person data assistant, a cell phone, etc.). A storage device 110 is shown plugged into a port of the computer system 300. In some embodiments this may be a USB port, but other embodiments may use other types of ports. As shown, the storage device is configured so that, when it is plugged in, it extends out from the computer system only a small distance, that distance being the smallest dimension of the storage device (excluding the plug, which may be inserted partly or completely into the computer system).

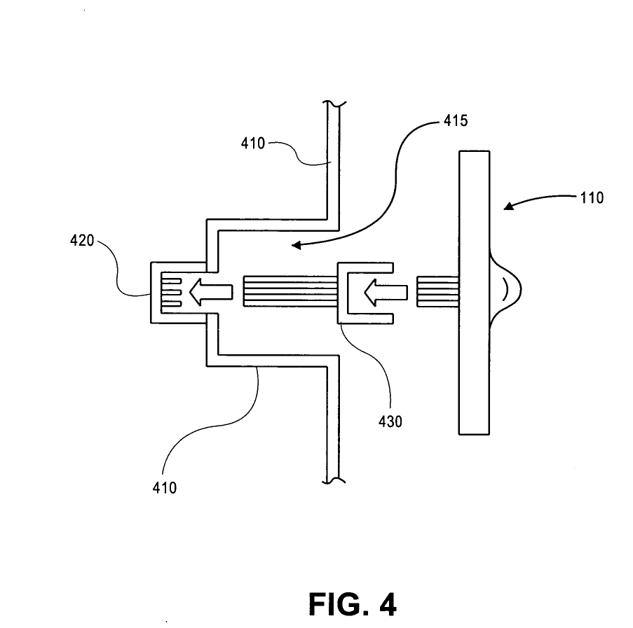

FIG. 4 shows an extension for a plug on a storage device, according to an embodiment of the invention. Some computer systems may have a recessed port, such as that shown by a cross-sectional view of an outer panel 410 of the computer system. For example, a USB port 420 may be at the deepest part of a recess 415 in the computer system. For these applications, the exemplary storage device may have a longer plug so that it reaches the port while the storage device is still located at the outer periphery of wall 410. In some embodiments this may be implemented with an extended-length plug, but other embodiments may use other techniques. For example, an add-on extender 430 may connect with both the storage device 110 and the recessed USB port, allowing the storage device 110 to fit flush against the side of the computer system while still making electrical connection with the port.

The foregoing description is intended to be illustrative and not limiting. Variations will occur to those of skill in the art. Those variations are intended to be included in the various embodiments of the invention, which are limited only by the spirit and scope of the following claims.

1. An apparatus, comprising
a storage device comprising:
at least one integrated circuit containing a solid-state non-volatile memory;
a body housing the at least one integrated circuit; and
an electrical plug physically connected to the body and electrically coupled to the at least one integrated circuit to provide a signal interface between the at least one integrated circuit and a connector of a computer system;
wherein a smallest overall dimension of the body is approximately parallel to an insertion axis of the electrical plug.

2. The apparatus of claim 1, wherein the signal interface is a universal serial bus interface.

3. The apparatus of claim 1, wherein the smallest overall dimension of the body structure is less than one-half inch.

4. The apparatus of claim 1, wherein the smallest overall dimension of the body structure is less than one-quarter inch.

5. The apparatus of claim 1, further comprising an extender to connect between the electrical plug and the connector of the computer system.

6. The apparatus of claim 1, wherein a largest overall dimension of the body is approximately perpendicular to an insertion axis of the electrical plug.

7. The apparatus of claim 1, further comprising a handle physically connected to the body.

8. A method, comprising:
inserting an electrical plug on a storage device into an electrical connector in a computer system such that a smallest overall dimension of the storage device is parallel to an insertion axis of the plug.

9. The method of claim 8, further comprising disconnecting the storage device from the connector by grasping a handle of the storage device and pulling the storage device away from the computer system.

10. The method of claim 8, wherein said inserting an electrical plug on the storage device comprises inserting the electrical plug on a flash drive.

11. A method, comprising:
connecting a storage device to a computer system by connecting an extender to an electrical plug on the storage device and connecting the extender to a connector in a recessed portion of an outer wall of the computer system, such that a largest dimension of the storage device is approximately parallel to the outer wall after said connecting is completed.

12. The method of claim 11, wherein said connecting the storage device comprises connecting a flash drive.
